(19) United States
(12) Patent Application Publication
(10) Pub. No.: US 2026/0231361 A1
(43) Pub. Date: Aug. 6, 2026

(54) FLUID CHANNEL CLOSURE VIA EXPANDING DAM

(71) Applicant: DELL PRODUCTS L.P., Round Rock, TX (US)

(72) Inventors: Brennan Seal, Austin, TX (US); Trevor Dawson, Austin, TX (US)

(21) Appl. No.: 19/043,648

(22) Filed: Feb. 3, 2025

(51) Int. Cl. H05K 7/20; G06F 1/20; H05K 5/02

(52) U.S. Cl. CPC H05K 7/20272; G06F 1/20; H05K 5/0212; G06F 2200/201

(57) ABSTRACT

A fluid containment subsystem for containing fluid leaks within a liquid-cooled information handling system includes an expandable dam positioned within a chassis of the liquid-cooled information handling system. A casing partially encloses the expandable dam within the chassis of the liquid-cooled information handling system. The expandable dam provides a predetermined clearance between the expandable dam and an adjacent structure of the chassis. The expandable dam is capable of closing the predetermined clearance by expanding in response to contact between the expandable dam and a fluid within the chassis of the liquid-cooled information handling system. In response to the contact, the expandable dam at least partially absorbs the fluid.

### FIELD OF THE DISCLOSURE

The present disclosure generally relates to information handling systems, and more particularly relates to liquid cooling of information handling systems.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A fluid containment subsystem for containing fluid leaks within a liquid-cooled information handling system includes an expandable dam positioned within a chassis of the liquid-cooled information handling system. A casing partially encloses the expandable dam within the chassis of the liquid-cooled information handling system. The expandable dam may provide a predetermined clearance between the expandable dam and an adjacent structure of the chassis. The expandable dam is capable of closing the predetermined clearance by expanding in response to contact between the expandable dam and a fluid within the chassis of the liquid-cooled information handling system. In response to the contact, the expandable dam at least partially absorbs the fluid.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a perspective view of an example liquid cooling subsystem for liquid cooling of an information handling system;

FIG. 2 is a partially exploded perspective view of an example fluid containment subsystem for an information handling system according to an embodiment of the present disclosure;

FIGS. 3A and 3B are cross-sectional views illustrating certain operative aspects of an example fluid containment subsystem according to an embodiment of the present disclosure;

FIG. 4 is a flow diagram of a method for according to an embodiment of the present disclosure; and

FIG. 5 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

For purposes of this disclosure, an information handling system is one that includes a liquid cooling apparatus or sub-system. Such an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, such an information handling system may be a computer, a server (such as a blade server or rack server), a network storage device, or any other such device and may vary in size, shape, performance, functionality, and price. The information handling system may include random access memory (RAM), one or more processing resources such as a central processing unit (CPU), graphics processing unit (GPU), hardware and/or software control logic, as well as ROM and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

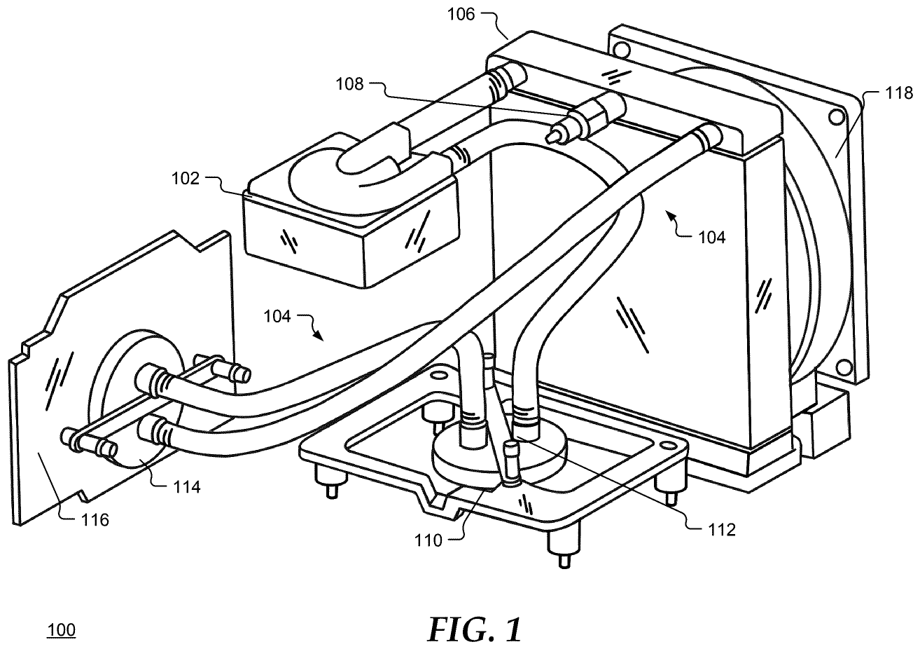

As the processing power of information handling systems continues to increase, the use of liquid cooling is expected to become more common owing to certain advantages that liquid cooling offers over other types of cooling. Referring to FIG. 1, an example liquid cooling system 100 is illustrated. Liquid cooling system 100 illustratively includes pump 102, tubing 104, heat exchanger 106, coolant port 108, CPU cold plate 110, clamp 112, GPU cold plate 114, memory heatsink 116, and fan 118. Pump 102 circulates a coolant such as water or other liquid (e.g., water plus additives) through tubing 104 and heat exchanger 106 to the components of the information handling system, including memory, CPU and/or GPU, as well as other components. The coolant circulates coolant, which in turn absorbing heat from the components and cooling the components via the cold plates, in a closed loop within the housing of the information handling system.

Notwithstanding the advantages of liquid cooling, there is the possibility that one or more components of the liquid cooling system may develop leaks over time due to vibration, thermal cycles, aging, misalignment of heat exchangers or cold plates, or the like. Any leak that exposes the components of the information handling system to liquid can cause corrosion or damage to the circuitry within the system's housing. In certain arrangements, a leak occurring in one information handling system also may damage one or more nearby information handling systems if the systems are sufficiently close to one another. For example, a leak may occur in one of multiple servers stacked on a vertical rack (an increasingly common configuration). If the leak is not detected early enough, the coolant may spill out of one server and adversely affect one or more servers below it on the vertical rack.

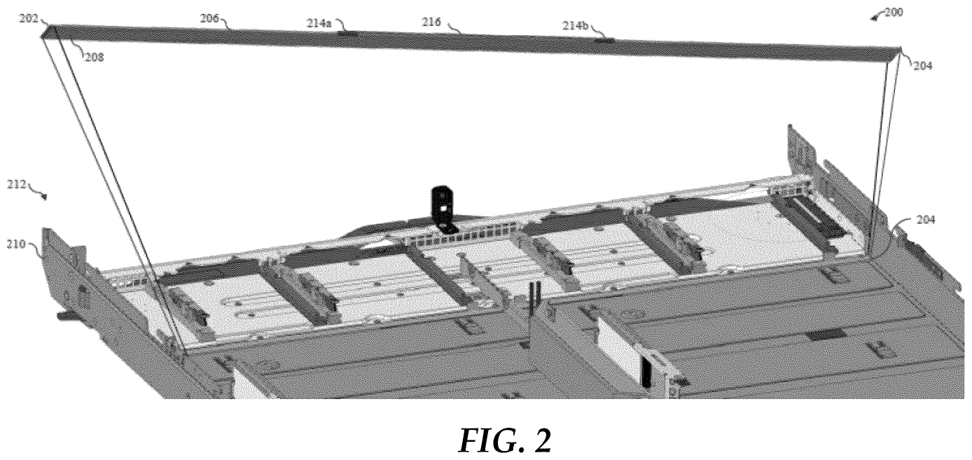

FIG. 2 illustrates an example fluid containment subsystem 200 for containing fluid leaks within a liquid-cooled information handling system. Illustratively, fluid containment subsystem 200 includes an expandable dam 202 and a casing 204. Expandable dam 202 may be partially enclosed by casing 204. Casing 204 illustratively includes a front side 206, a bottom side 208, and a back side (not explicitly shown). Casing 204 may be secured to a base 210 of a chassis 212, which houses the components of an information handling system.

In certain embodiments, one or more notches, or openings, (shown by notches 214a and 214b) may be formed in front side 206 of casing 204. The opening(s) may expose expandable dam 202 to fluid by permitting the fluid to enter casing 204 via the opening(s). Additionally, in some embodiments, casing 204 includes wicking flange 216. Wicking flange 216 may be formed by folding an outer portion of casing 204 over itself. The folding creates a narrow gap that may induce capillary action by which a wicking flange 216 may draw fluid along the length of casing 204 and to the one or more notches formed in front side 206. In still other embodiments, all or a portion of the external surface of front side 206 may be hydrophobic. For example, the external surface may be coated with a fluoropolymer, such as polytetrafluoroethylene (PTFE), which is inherently hydrophobic due to strong carbon-fluorine bonds that are highly resistant to water and other fluids.

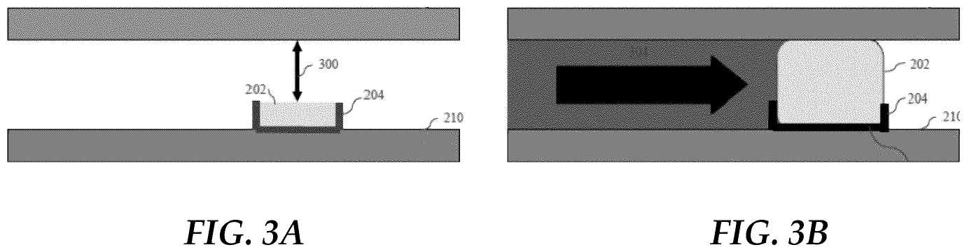

FIGS. 3A and 3B illustrate two of the operative aspects of fluid containment subsystem 200. In FIG. 3A, as shown, fluid containment subsystem 200 provides clearance 300 between expandable dam 202 and a structure 302 within a chassis, such as chassis 212 of FIG. 2. Structure 302 may be a tempan, mounting bracket, support structure, or other structure. It is not uncommon for a conventional dam to be damaged when the tempan (or other structure) is being installed in a chassis, such as chassis 212 of FIG. 2. Providing clearance 300 (e.g., at least 2.5 cm) mitigates the risk of damage to expandable dam 202 during the installation of structure 302. Providing clearance 300 may further provide for an air flow within the liquid cooled information handling system.

Referring now to FIG. 3B, while providing clearance 300, fluid containment subsystem 200 nonetheless is capable of containing fluid if a coolant leak occurs, thus preventing fluid from reaching areas within a chassis, such as chassis 212 of FIG. 2, containing critical components of the information handling system. The containment is the result of expandable dam 202 expanding in response to physical contact between the expandable dam and fluid 304 within chassis 212 of the information handling system, as illustrated in FIG. 3B. Fluid 304 may enter casing 204 via one or more notches formed in the casing, thereby coming into physical contact with expandable dam 202.

In certain embodiments, expandable dam 202 may be formed of a semi-solid material mixture including a hydrogel or other polymers that expand when coming into physical contact with a liquid. Gel polymerization causes expandable dam 202 to expand upward from bottom side 208 of casing 204. The expansion results in the closure of channels blocked by expandable dam 202. Thus, in response to a leak of coolant from the liquid-cooling apparatus or subsystem of a liquid-cooled information handling system, fluid containment subsystem 200 operates to contain the leak. Moreover, the risk of extensive damage within a chassis, such as chassis 212 of FIG. 2, may be further mitigated with the absorption of leaked coolant by expandable dam 202, which is capable of absorbing a large quantity of fluid.

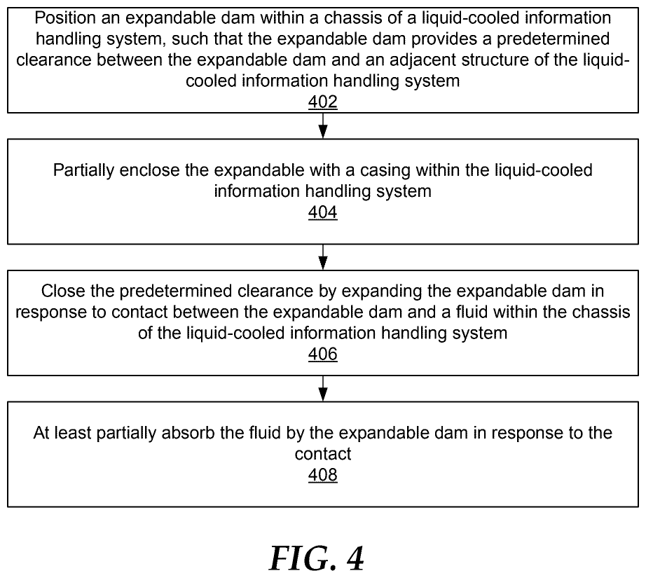

FIG. 4 illustrates an example method 400 of containing leaked liquids within a liquid-cooled information handling system. It will be readily appreciated that not every method step set forth in this flow diagram is always necessary, and that certain steps of the methods may be combined, performed simultaneously, in a different order, or perhaps omitted, without varying from the scope of the disclosure.

At block 402, method 400 includes positioning an expandable dam within a chassis of the liquid-cooled information handling system. The expandable dam provides a predetermined clearance between the expandable dam and an adjacent structure of the liquid-cooled information handling system. The predetermined clearance may be at least 2.5 centimeters. At block 404, method 400 includes partially enclosing the expandable dam within a casing within the liquid-cooled information handling system.

At block 406, in response to contact between the expandable dam and a fluid within the chassis of the liquid-cooled information handling system, the expandable dam closes the predetermined clearance. The closure is the result of the expandable dam expanding in response to physical contact between the expandable dam and the fluid. The closure contains the fluid, preventing the fluid from flowing past the expandable dam. At block 408, in response to the contact, the expandable dam at least partially absorbs the fluid.

One or more notches may be formed in surface portions of the casing. The one or more notches permit fluid to enter the casing and to come into physical contact with the expandable dam, which causes the expansion of the expandable dam. Additionally, the casing may include a wicking flange extending along a portion of an exterior of the casing. The wicking flange may draw fluid to the one or more notches so that the fluid comes into physical contact with the expandable dam. The wicking flange may be an overhanging edge formed by folding an outer edge of the casing over itself. The wicking flange may extend along a portion of an exterior of the casing between a pair of notches, which may be formed in surface portions of the casing on respective ends of the wicking flange. An outer surface of the casing may be coated with hydrophobic material.

Note that as illustrated herein, an expandable dam is provided with a predetermined distance between the expandable dam and an adjacent structure of the information handling system, but this is not necessarily so. For example, an expandable dam may be provided without any adjacent structure. Here, it may be understood that the expandable dam will mitigate liquid coolant leaks that occur behind the expandable dam, but may not mitigate exceeding large liquid coolant leaks, and that such large liquid coolant leaks may overflow the expandable dam. However, utilized in combination with one or more leak detection system, the expandable dam in this case may permit a reasonable response time for a service technician to mitigate further liquid coolant leakage, as needed or desired.

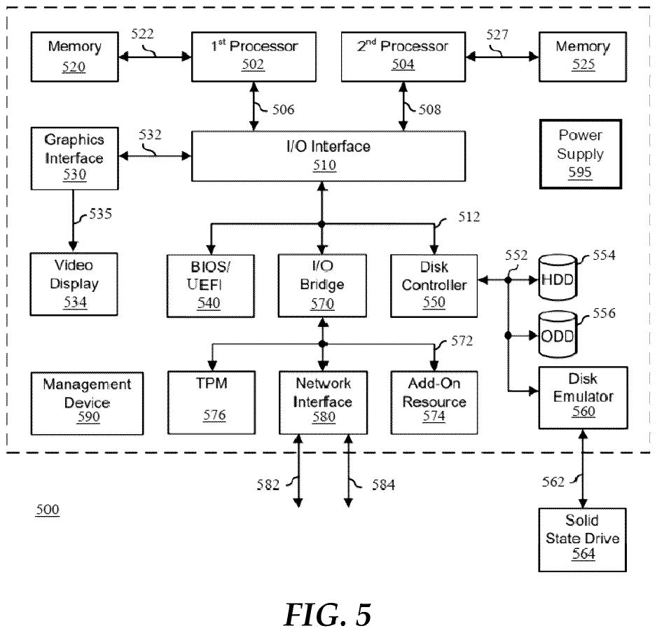

FIG. 5 shows a generalized embodiment of an information handling system 500 according to an embodiment of the present disclosure. Information handling system 500 may be substantially like a liquid-cooled information handling system that includes a fluid containment subsystem such as the one described with reference to FIGS. 2 and 3A and B. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 564, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 564, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532 and provides a video display output 536 to a video display 534. In a particular embodiment, information handling system 500 includes separate memories that are dedicated to each of processors 502 and 504 via separate memory interfaces. An example of memories 520 and 530 includes random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 4394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512 or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500.

Management device 590 can operate off a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

That which is claimed is:

1. A fluid containment subsystem for containing fluid leaks within a liquid-cooled information handling system, the fluid containment subsystem comprising:
an expandable dam positioned within a chassis of the liquid-cooled information handling system; and
a casing partially enclosing the expandable dam within the chassis of the liquid-cooled information handling system,
wherein the expandable dam provides a predetermined clearance between the expandable dam and an adjacent structure of the chassis,
wherein the expandable dam is capable of closing the predetermined clearance by expanding in response to contact between the expandable dam and a fluid within the chassis of the liquid-cooled information handling system.

2. The fluid containment subsystem of claim 1, wherein a plurality of notches is formed in surface portions of the casing.

3. The fluid containment subsystem of claim 1, wherein the casing includes a wicking flange extending along a portion of an exterior of the casing.

4. The fluid containment subsystem of claim 3, wherein the wicking flange is an overhanging edge formed by folding an edge of the casing over itself.

5. The fluid containment subsystem of claim 1, wherein the casing includes a wicking flange extending along a portion of an exterior of the casing and a pair of notches formed in surface portions of the casing on respective ends of the wicking flange.

6. The fluid containment subsystem of claim 1, wherein the casing includes an outer surface coated with a hydrophobic material.

7. The fluid containment subsystem of claim 1, wherein, in response to the contact, the expandable dam at least partially absorbs the fluid.

8. The fluid containment subsystem of claim 1, wherein the expandable dam is configured to expand through gel polymerization in response to the at least partially absorbing of the fluid.

9. A method of containing leaked fluids within a liquid-cooled information handling system, the method comprising:
positioning an expandable dam within a chassis of the liquid-cooled information handling system, wherein the expandable dam provides a predetermined clearance between the expandable dam and an adjacent structure of the liquid-cooled information handling system; and
partially enclosing the expandable dam with a casing within the liquid-cooled information handling system,
wherein the expandable dam is capable of closing the predetermined clearance by expanding in response to contact between the expandable dam and a fluid within the chassis of the liquid-cooled information handling system.

10. The method of claim 9, wherein a plurality of notches is formed in surface portions of the casing.

11. The method of claim 9, wherein the casing includes a wicking flange extending along a portion of an exterior of the casing.

12. The method of claim 11, wherein the wicking flange is an overhanging edge formed by folding an outer edge of the casing over itself.

13. The method of claim 9, wherein the casing includes a wicking flange extending along a portion of an exterior of the casing and a pair of notches formed in surface portions of the casing on respective ends of the wicking flange.

14. The method of claim 9, wherein the casing includes an outer an outer surface coated with a hydrophobic material.

15. The method of claim 9, wherein, in response to the contact, the expandable dam at least partially absorbs the fluid.

16. The method of claim 9, wherein the expandable dam is configured to expand through gel polymerization in response to the at least partially absorbing of the fluid.

17. A liquid-cooled information handling system, comprising:
a chassis having a chassis base;
a memory contained within the chassis;
one or more processing resources contained withing the chassis and operatively coupled with the memory via a bus; and
a fluid containment subsystem including:
an expandable dam positioned within the chassis of the liquid-cooled information handling system; and
a casing partially enclosing the expandable dam within the chassis of the liquid-cooled information handling system,
wherein the expandable dam provides a predetermined clearance between the expandable dam and an adjacent structure of the chassis,
wherein the expandable dam is capable of closing the predetermined clearance by expanding in response to contact between the expandable dam and a fluid within the chassis of the liquid-cooled information handling system,
wherein, in response to the contact, the expandable dam at least partially absorbs the fluid.

18. The liquid-cooled information handling system of claim 17, wherein a plurality of notches is formed in surface portions of the casing.

19. The liquid-cooled information handling system of claim 17, wherein the casing includes a wicking flange extending along a portion of an exterior of the casing.

20. The liquid-cooled information handling system of claim 17, wherein the casing includes an outer surface coated with a hydrophobic material.
